(19) United States
(12) Patent Application Publication
(10) Pub. No.: US 2026/0014665 A1
(43) Pub. Date: Jan. 15, 2026

(54) DOUBLE-SIDE GRINDING APPARATUS AND METHODS HAVING A WHEELBASE WITH POROUS ABRASIVE MEMBERS

(71) Applicant: GlobalWafers Co., Ltd., Hsinchu (TW)

(72) Inventors: Cheulwon Choi, Chungcheongnam-do (KR); Jaehoon Lee, Chungcheongnam-do (KR); Byungchul Lee, Chungcheongnam-do (KR); Jongsun Kim, Chungcheongnam-do (KR); Changsun Lee, Chungcheongnam-si (KR); Minkyu Lee, Gyeonggi-do (KR)

(21) Appl. No.: 19/264,218

(22) Filed: Jul. 9, 2025

Related U.S. Application Data
(60) Provisional application No. 63/669,783, filed on Jul. 11, 2024.

(51) Int. Cl. B24B 37/20; B24B 37/08; H01L 21/02

(52) U.S. Cl. CPC B24B 37/20; B24B 37/08; H01L 21/02013

(57) ABSTRACT

A grinding wheel includes a wheelbase including an exterior wall, an inner surface positioned radially within the exterior wall, the inner surface defining a central opening extending axially through the wheelbase, an end wall extending between the inner surface and the exterior wall, and a protruding wall extending axially from the end wall and circumferentially about the central opening. The inner surface defines an inner groove extending around the central opening. The grinding wheel further includes abrasive members attached to the wheelbase and extending axially outward from the end wall.

### CROSS-REFERENCE TO RELATED APPLICATION

This application claims the benefit of U.S. Provisional Patent Application No. 63/669,783, filed Jul. 11, 2024, which is incorporated herein by reference it its entirety.

### FIELD OF THE DISCLOSURE

The field of the disclosure relates generally to simultaneous double-side grinding of semiconductor wafers and more particularly to double-side grinding apparatus and methods for double-side grinding that incorporate a wheelbase with porous abrasive members.

### BACKGROUND

Semiconductor wafers are commonly used in the production of integrated circuit (IC) chips on which circuitry is printed. The circuitry is first printed in miniaturized form onto surfaces of the wafers, then the wafers are broken into circuit chips. But this smaller circuitry requires that wafer surfaces be extremely flat and parallel to ensure that the circuitry can be properly printed over the entire surface of the wafer. To accomplish this, a grinding process is commonly used to improve certain features of the wafers (e.g., flatness and parallelism) after they are cut from an ingot.

Simultaneous double-side grinding operates on both sides of the wafer at the same time and produces wafers with highly planarized surfaces. It is therefore a desirable grinding process. Apparatuses used in such double-sided grinding process often include a pair of identical grinding wheels that are positioned on opposed sides of the wafers. An example grinding wheel is disclosed in U.S. Patent Application Publication No. 2024/0217053, which is hereby incorporated by reference in its entirety.

At least some wheelbases used in grinding wheels include abrasive stones fixed to the wheelbases. The use of high porosity superabrasive stones with the grinding wheels is desirable to achieve reduced surface or subsurface wafer damage, higher strength of ground wafers, and maintain stable flatness of the wafers (for example, Warp or “WARPBF”, Bowing profile or “BOWBF”, site flatness quality requirements or “SFQR”, Edge Site Front surface-referenced Least Squares/Range or “ESFQR”, Total Thickness Variation or “TTV” and nanotopography, etc.) during grinding process.

A need exists for double-side grinding structures that may be used with high porosity superabrasive stones and reduce erosion to the stones.

This section is intended to introduce the reader to various aspects of art that may be related to various aspects of the disclosure, which are described and/or claimed below. This discussion is believed to be helpful in providing the reader with background information to facilitate a better understanding of the various aspects of the present disclosure. Accordingly, it should be understood that these statements are to be read in this light, and not as admissions of prior art.

### SUMMARY

In one aspect a grinding wheel for use with a double-side wafer grinding apparatus is provided. The grinding wheel includes a wheelbase including an exterior wall, an inner surface positioned radially within the exterior wall, the inner surface defining a central opening extending axially through the wheelbase, an end wall extending between the inner surface and the exterior wall, and a protruding wall extending axially from the end wall and circumferentially about the central opening. The inner surface defines an inner groove extending around the central opening. The grinding wheel further includes abrasive members attached to the wheelbase and extending axially outward from the end wall.

In another aspect, a method for double-sided grinding of a semiconductor structure is provided. The method includes positioning the semiconductor structure between first and second grinding wheels. Each grinding wheel includes a wheelbase including an exterior wall, an inner surface positioned radially within the exterior wall and defining a central opening extending axially through the wheelbase, an end wall extending between the inner surface and the exterior wall, and a protruding wall extending axially from the end wall and circumferentially about the central opening. The inner surface defines an inner groove extending around the central opening. The grinding wheel further includes abrasive members attached to the wheelbase and extending axially outward from the end wall. The method further includes grinding the semiconductor structure by contacting the first and second grinding wheels with the semiconductor structure and rotating the first and second grinding wheels relative to each other.

In yet another aspect, a double-side grinding apparatus is provided. The double-side grinding apparatus includes first and second grinding wheels, each grinding wheel has a rotational axis and includes a wheelbase including an exterior wall, an inner surface positioned radially within the exterior wall, the inner surface defining a central opening extending axially through the wheelbase, an end wall extending between the inner surface and the exterior wall, and a protruding wall extending axially from the end wall and circumferentially about the central opening. The inner surface defines an inner groove extending around the central opening. The first and second grinding wheels each include abrasive members attached to the wheelbase and extending axially outward from the end wall.

Various refinements exist of the features noted in relation to the above-mentioned aspects of the present disclosure. Further features may also be incorporated in the above-mentioned aspects of the present disclosure as well. These refinements and additional features may exist individually or in any combination. For instance, various features discussed below in relation to any of the illustrated embodiments of the present disclosure may be incorporated into any of the above-described aspects of the present disclosure, alone or in any combination.

### BRIEF DESCRIPTION OF THE DRAWINGS

FIG. 1 is a perspective exploded view of a double-side grinding apparatus;

FIG. 2 is a cross-section view of an example grinding wheel for use with the double-side grinding apparatus of FIG. 1, including a conventional wheelbase and abrasive members;

FIG. 3 is an image showing fluid flow from the grinding wheel of FIG. 2 during a grinding process;

FIG. 4 is an image showing a portion of the grinding wheel of FIG. 2 after repeated use;

FIG. 5 illustrates box plots of a BOW profile for semiconductor structures simultaneous double-side ground by different flow rates of grinding fluid;

FIG. 6 is a first image showing a perspective view of an example wheelbase of the present disclosure for use with the double-side grinding apparatus shown in FIG. 1;

FIG. 7 is a second image showing another perspective view of the wheelbase shown in FIG. 7;

FIG. 8 is a cross-section view of an example grinding wheel for use with the double-side grinding apparatus of FIG. 1, including the wheelbase of FIG. 6 and abrasive members;

FIG. 9 is an image showing fluid flow from the grinding wheel of FIG. 8 during a grinding process;

FIG. 10 shows images of a portion of the grinding wheel of FIG. 8 after grinding a first number of wafers;

FIG. 11 shows images of a portion of the grinding wheel of FIG. 8 after grinding a second number of wafers;

FIG. 12 shows images of a portion of the grinding wheel of FIG. 8 after grinding a third number of wafers;

FIG. 13 shows images of a portion of the grinding wheel of FIG. 8 after grinding a fourth number of wafers;

FIG. 14 illustrates box charts showing a lifespan of grinding wheels using the wheelbase of FIG. 2 compared with grinding wheels using the wheelbase of FIG. 6;

FIG. 15 is a time series plot of BOW profiles for semiconductor structures simultaneous double-side ground using the grinding wheel of FIG. 2; and

FIG. 16 is a time series plot of BOW profiles for semiconductor structures simultaneous double-side ground using the grinding wheel of FIG. 8.

Corresponding reference characters indicate corresponding parts throughout the drawings.

### DETAILED DESCRIPTION

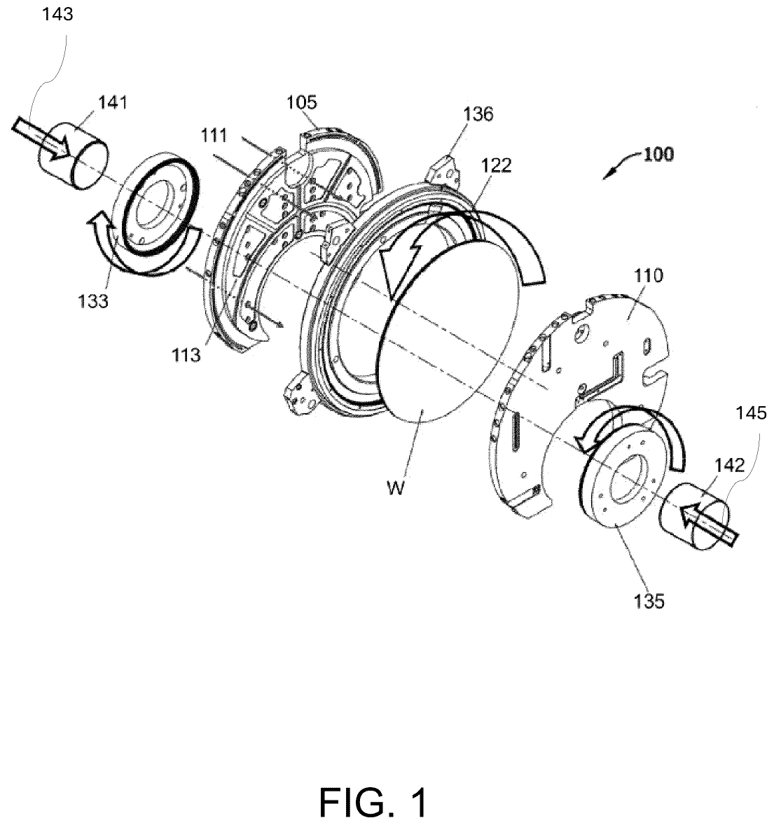

An example double-side grinding apparatus 100 for use in embodiments of the present disclosure is shown in FIG. 1. The double-side grinding apparatus 100 (which may also be referred to herein as a “simultaneous double-side grinding apparatus”) includes a pair of hydrostatic pads 105, 110 that generate water cushions or “pockets” 113 through a source of water 111. The semiconductor structure W (which may also be referred to herein as a “wafer”) is guided between the water cushions 113, thereby “clamping” the wafer W in a generally vertical alignment. The wafer W is secured in a carrier ring 122. The carrier ring 122 (and wafer W secured therein) rotates within a hydrostatic guide roller 136. A pair of first and second grinding wheels 133, 135 (“left” and “right” grinding wheels) extend through the hydrostatic pads 105, 110. The pair of grinding wheels 133, 135 rotate in opposite directions relative to each other. The grinding wheels 133, 135 are connected with shafts 141, 142, which extend through the grinding wheels respectively. In some embodiments the shafts 141, 142 include air spindles, though in other embodiments any suitable shafts may be used. An electric motor rotates the grinding wheels 133, 135 and grinding water is provided through each of the shafts 141, 142, along the direction arrows 143, 145, respectively. The grinding wheels 133, 135 may include full peripheral contact with the wafer W as they rotate.

Generally, the double-side grinding apparatus 100 may be adapted to process any size semiconductor structure W such as structures having a diameter of 200 mm or more, 300 mm or more, or 450 mm or more. The semiconductor structure W may be a single crystal silicon wafer. In other embodiments, the semiconductor structure W is made of silicon carbide, sapphire, or Al₂O₃. The semiconductor structure may be a layered structure or may be a bulk wafer.

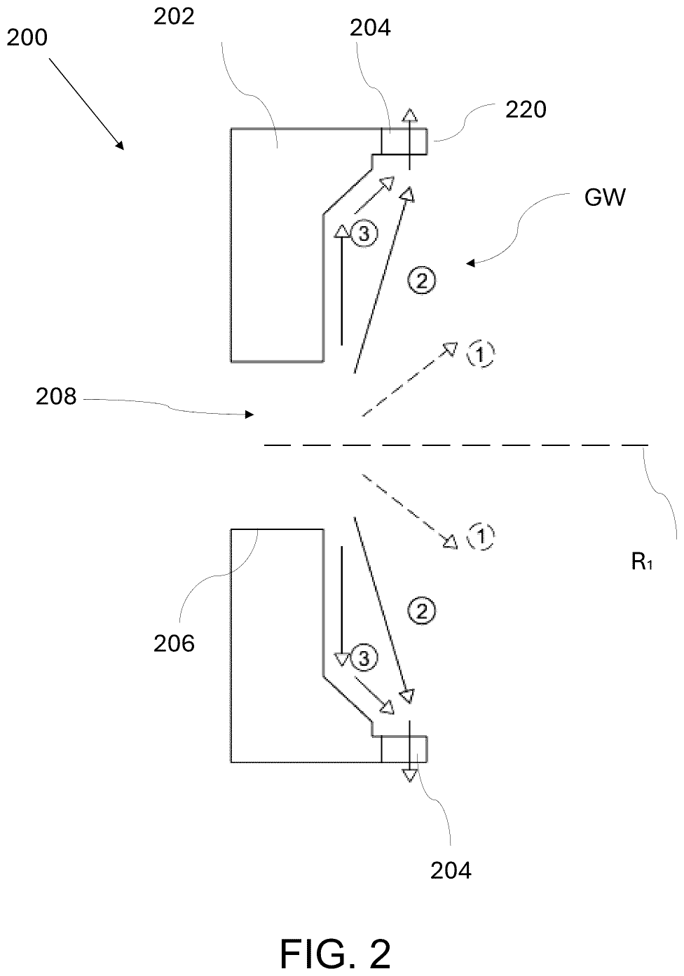

An example grinding wheel 200 for use with the apparatus 100 is shown in FIGS. 2-4. Referring to FIG. 2, which shows a cross-section of the grinding wheel 200, the grinding wheel 200 includes a wheelbase 202 and a plurality of abrasive members 204 attached to the wheelbase 202. The wheelbase 202 is a conventional wheel base and includes an inner surface 206 which defines a central opening 208 through which the grinding water GW, also referred to herein as “grinding fluid”, is directed during a grinding process. The grinding wheel 200 rotates about a rotational axis, indicated at R₁, extending through the central opening 208.

In the example of FIG. 2, the abrasive members 204 include high porosity superabrasive stones. High porosity superabrasive stones for double-side grinding processes have exhibited excessive erosion on their surfaces, generated from the collision between grinding water, in the form of droplets, and the abrasive stones, resulting in reduced lifespan. Additionally, the design of some wheelbases are not proper to supply the grinding water to the distal wafer facing surfaces of high porosity superabrasive stones. As a result, at the beginning of wheel lifespan, the ground wafers have a “negative BOW profile” and the useable lifespan of the grinding wheels is reduced. Additionally, tensile residual stresses, which are originated by the thermal loads during grinding process, can weaken the mechanical properties of the wafer during grinding process. Reducing thermal loads generated from the grinding process is important to achieve the higher strength and the improved flatness of the ground wafers with less surface damage.

High porosity superabrasive stones are desirable for achieving higher strength of wafers, maintaining stable flatness, and reducing surface or subsurface damage by reducing thermal loads generated during grinding processes. Tensile residual stresses, which are originated by the thermal loads during the grinding process, can weaken the mechanical properties of the wafer during the grinding process. Reducing thermal load generated from the grinding process is important to achieve the higher strength and the improved flatness of the ground wafers W with reduced surface damage.

The porosity of abrasive stones of grinding wheels reduces the thermal loads (e.g., caused by grinding resistance) during the grinding process. The porosity of the stones controls the contact area between the surface of wafers and the composite microstructure of superabrasive stones. Additionally, pores typically provide access to grinding fluids (such as coolant and lubricant) and facilitate movement of coolant around the microstructure. The pores permit the clearance of material (e.g., chips or swarf) removed from the wafers being ground, which tend to promote more efficient cutting. Increased porosity of abrasive stones reduces the grinding surface temperature and resultant thermal and residual stresses during the grinding process.

One drawback to increased porosity of the stones is that it may adversely affects the consistency of grinding. For example, the abrasive members 204 include a superabrasive component and a vitrified bond component in which the superabrasive component is dispersed. The vitrified bond component may define pores occupying greater than about 30 percent, 40 percent, 50 percent, 60 percent, or 70 percent of the total volume of the abrasive members. In the example embodiment, the abrasive members 204 pores occupy greater than about 50 percent of the total volume of the abrasive members 204. To increase the porosity of the abrasive stones by the designed and fixed volume of vitrified superabrasive structure, the volume percent of each element (glass powder, binder, pore-forming agent) of the vitrified bond component must be changed.

This kind of design change of the volume percent among elements of the vitrified bond component may lead to structural weakening of superabrasive members 204. For example, in case of increasing the porosity of vitrified superabrasive member 204 by ten percent, the same of amount the glass powder must be reduced by ten percent in the fixed volume of superabrasive stones at the same time. As a result of the lack of the glass powder, the high porosity vitrified abrasive structures have weaker structures than the low porosity vitrified abrasive structures.

The increased volume of pores of the vitrified superabrasive structure acts as defects during grinding process. During the double-side grinding process, the wheels 200 are rotating over 5,000 rotations per minute (“rpm”). At the same time, the grinding water GW coming from the central opening 208 through the shaft 141, 142 (shown in FIG. 1), is sprayed directly in a radiating spray pattern, in the form of water droplets, into the surface of high porosity abrasive members 204. The collision between the sprayed grinding water and the surface of high porosity abrasive stones, along the flow path (2) happens during grinding cycle continuously.

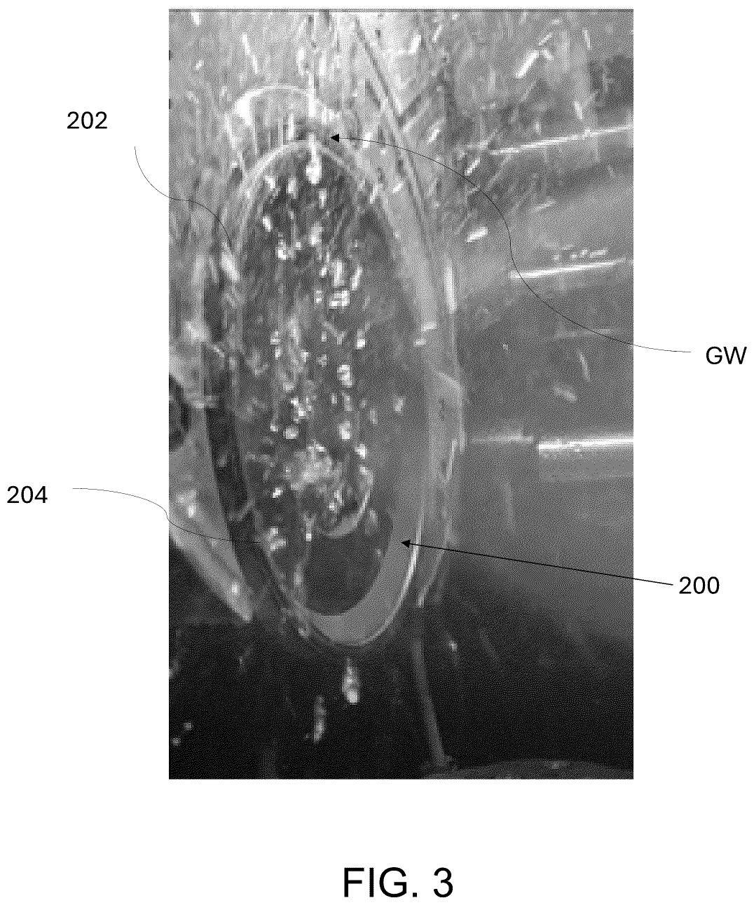

As shown in FIG. 3, the generated large amount of droplets of grinding water GW from the center of the wheelbase 202 are sprayed at high velocity on the surface of high porosity abrasive stones continuously with high speed due to the rotational velocity of the grinding wheel 200. The spray pattern of grinding water GW droplets used with the grinding wheel 200 result in high-speed collision between the grinding water GW, in form of droplets, and the surfaces of the abrasive members.

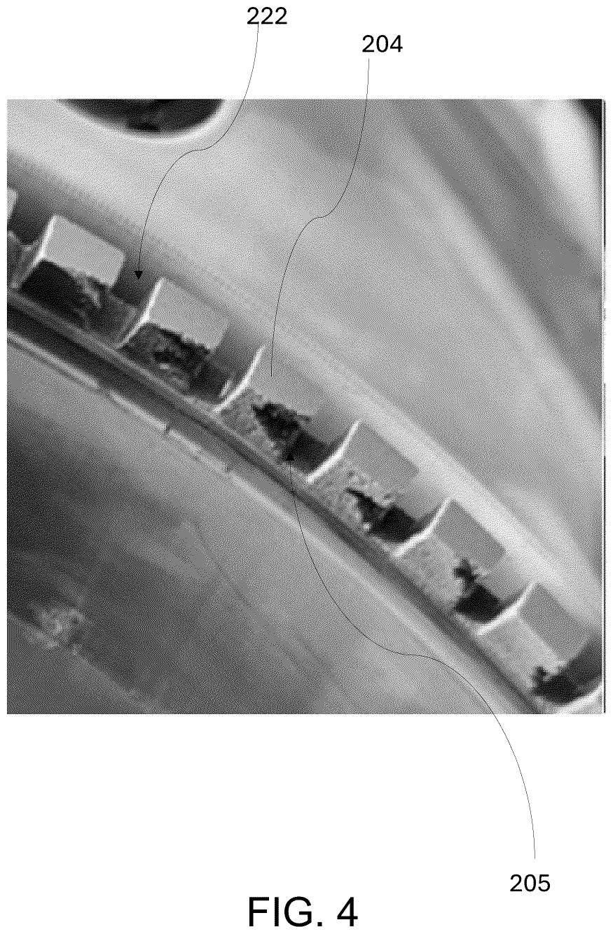

As a result of the collision between droplets of the radiating spray and the abrasive members 204, erosion of the abrasive members 204 is increased over time from use. Referring to FIG. 4, as shown the abrasive members 204 include eroded defects 205 formed in sides of the high porosity abrasive members 204. As a structural weak point of the high porosity superabrasive members 204, the pores can play a role of starting point of the erosion. The increased volume of the pore reduces the resistance to erosion caused by the collision between the grinding water and the surface of high porosity superabrasive stones.

Referring back to FIG. 2, another limitation of the radiating spray pattern from the wheel 200 is that insufficient grinding water GW is directed to an area between the distal ends 220 of the abrasive members 204 and the wafer W (shown in FIG. 1). As a result, wafers W ground using the wheel 200 may have negative BOW profiles.

For example, as shown in FIG. 2, the grinding water GW, is sprayed in an irregular radiating pattern toward the surface of rotating wafer W (shown in FIG. 1), along the flow path (1) and at the abrasive members 304 along the flow path (2) but is not efficiently supplied to the area between the surface of wafer and the distal ends 220 of the abrasive members 204, where grinding occurs. At the beginning of the wheel's lifespan, the abrasive members have the greatest axial height and most of grinding water GW is sprayed on the surface of rotating wafer along the flow path (1), and at the surface of superabrasive stones along the flow path (2). Some of the grinding water is sprayed along the direction arrow, indicated at “3”, and passes through a slit 222 (shown in FIG. 4) between the abrasive members 204, and therefore cannot reach to the distal end 220 of abrasive members 204 efficiently.

One limitation of the conventional wheelbase 202 shown in FIG. 2 is the promotion of a negative BOW profile of wafers W that are double side ground at the beginning of the lifespan of the wheel 200. For example, in the double-side grinding process, the grinding water GW is used to remove the silicon sludge from the area between the surface of wafer and the distal ends 220 (shown in FIG. 2) of the abrasive members 204, where grinding occurs. If insufficient grinding water GW is supplied between the wafer surface and the distal ends 220 of the abrasive members 204, the sludge of silicon cannot be removed efficiently from wafers and abrasive members during grinding process, which leads to the increase of thermal load (grinding resistance), resulting in a negative BOW profile of the wafers.

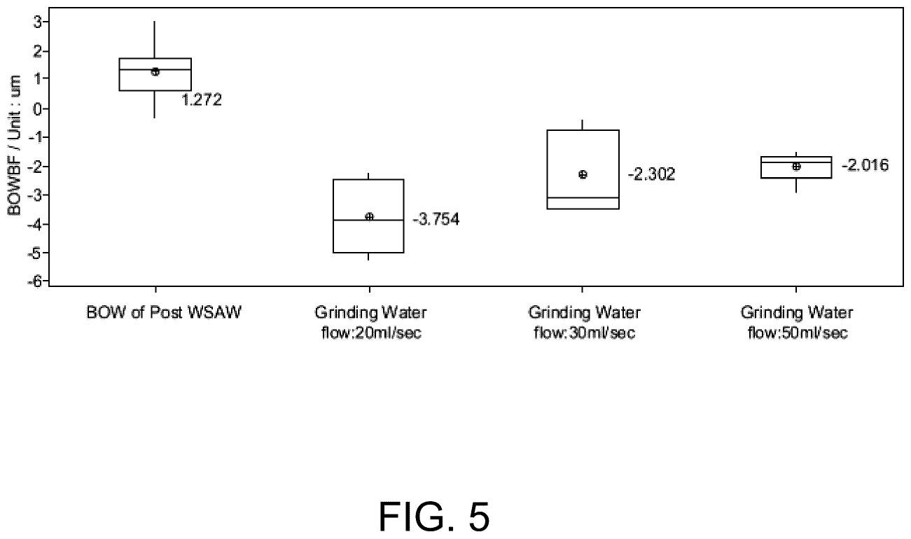

As shown in FIG. 5, the BOW profile of ground wafers can be changed to negative BOW profile by decreasing a flow rate of the grinding water, during the double-side grinding process. Unlike other areas of the rotating wafer, a central area of the rotating wafer contacts with the rotating grinding wheel, continuously, over the double-side grinding cycle. As a result, the largest amounts of removal of material occurs at the center of the rotating wafer. Specially, the amount of removal of the front side of rotating wafer is bigger than the amount of removal of the backside according to the rotating direction of grinding wheels 200 and a wafer W.

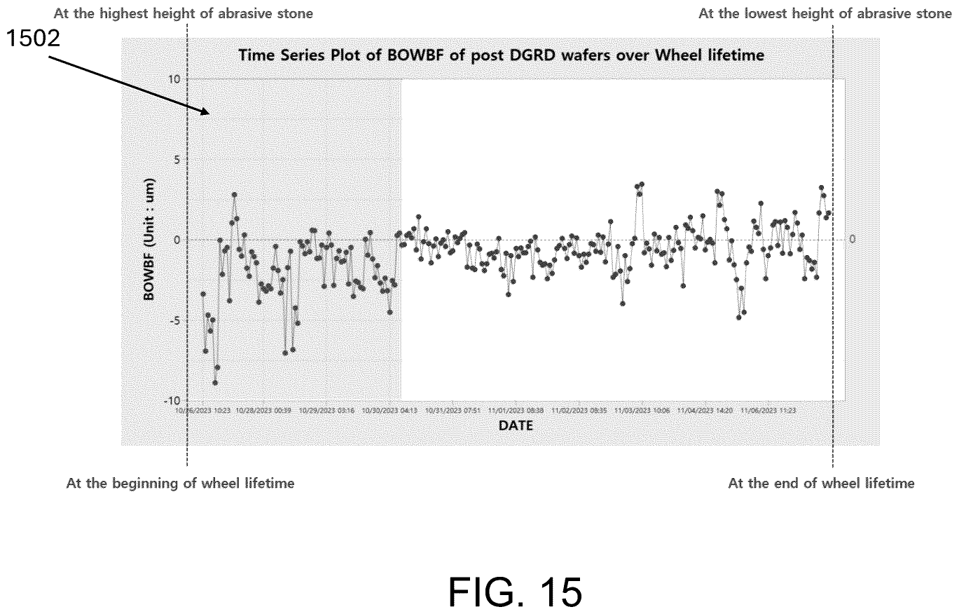

Referring to FIG. 15, a time series plot showing the BOW profiles for wafers formed using the wheelbase 202 of FIG. 2 is shown. In FIG. 15, the BOW profiles are indicated in microns. As shown in FIG. 15, at the start of the lifespan of the grinding wheel 200, the BOW profiles are generally negative, as indicated by the shaded region 1502.

With respect to the conventional wheelbase 202, because insufficient grinding water GW is directed to the distal ends 220 of high porosity superabrasive members 204 efficiently, when the abrasive members 204 are at their tallest (e.g., at the start of the lifespan of the grinding wheel 200), the height of slits 222 (shown in FIG. 4) between the members 204 is at its highest value, since the height (i.e., axial extent) of the abrasive members 204 are at their highest value. The grinding water GW flowing through the surface of wheelbase 202 can easily flow to the outside of the grinding wheel 200 through the slits 222 and less grinding water is directed to the distal ends 220 of the abrasive members 304. At the beginning of wheel lifespan, it is difficult to remove the sludge of silicon from the distal ends 220 of high porosity superabrasive stone, at least in part due to the increased heights of the abrasive members 204. The buildup of silicon sludge at the distal ends 220 of abrasive members 304 can lead to generating negative BOW profile in the wafers, as shown in FIG. 15, due to the increase of grinding resistance. In contrast, in the middle of wheel lifespan or at the end of wheel lifespan for the grinding wheel 200, the height of abrasive members 204 decrease according to the decrease of height of high porosity superabrasive stones and less grinding water is passed through the slits.

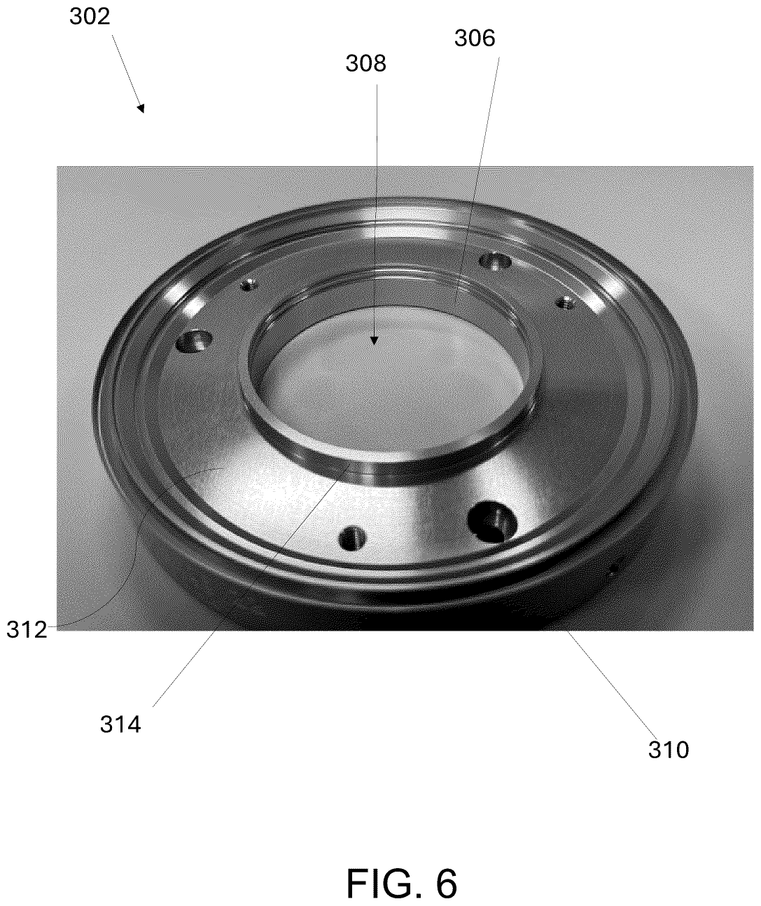

FIGS. 6-13 show an example wheelbase 302 of the present disclosure and grinding wheel 300 incorporating the wheelbase 302 for use with the grinding apparatus 100 of FIG. 1. In FIGS. 6-8 the abrasive members are not shown, though it should be understood that the wheelbase 302 is configured to be used as a grinding wheel with the same high porosity super abrasive stones, as described with respect to FIGS. 2-4.

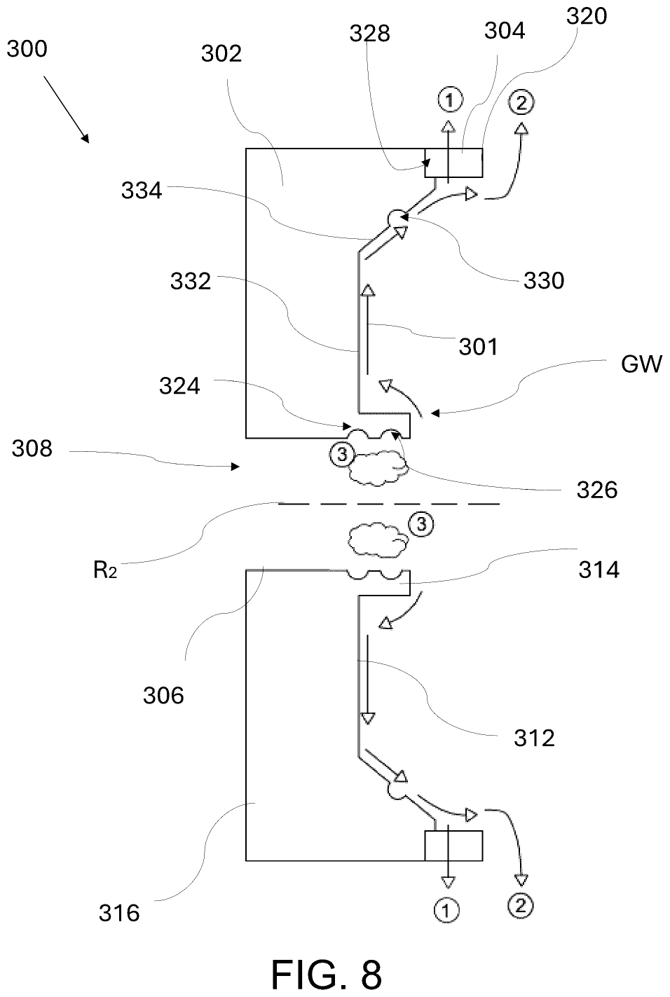

Referring to FIG. 6, the wheelbase 302 includes an exterior wall 310, an inner surface 306, an end wall 312, and a protruding wall 314. The inner surface 306 is positioned radially within exterior wall 310 and defines a central opening 308 therein. The central opening 308 receives the supply of grinding water GW (shown in FIG. 8) therethrough (e.g., through the shaft 141, shown in FIG. 1). The central opening 308 extends axially, along the rotational axis R₂ (shown in FIG. 8) through the wheelbase 302.

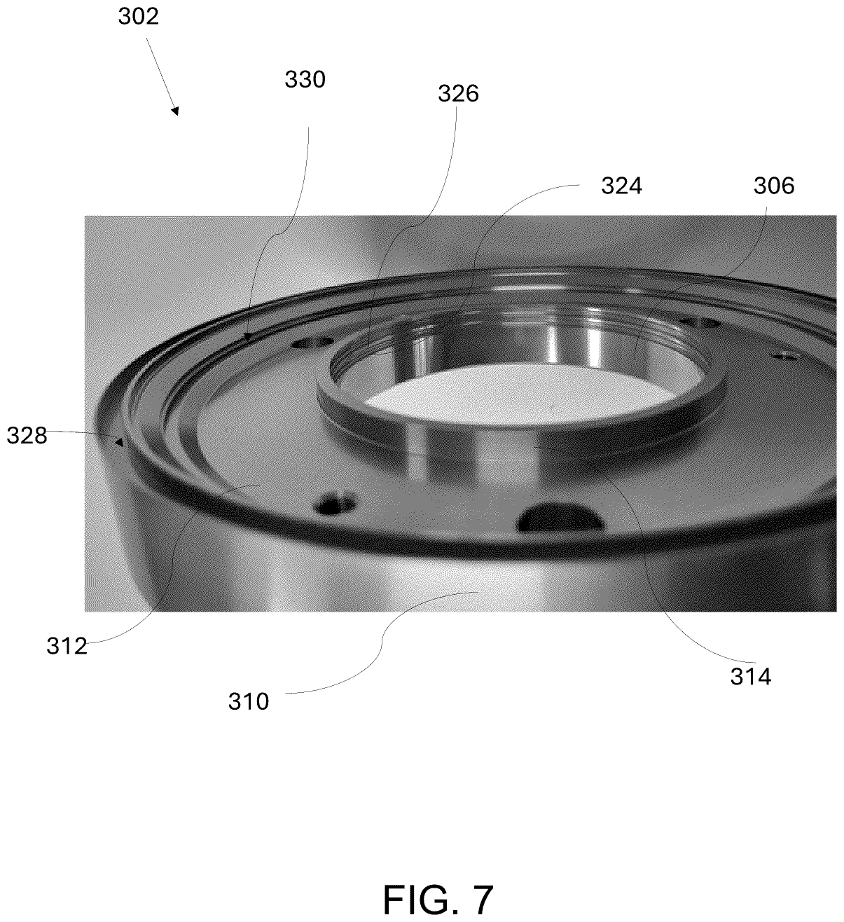

Referring to FIG. 6, the end wall 312 extends between the inner surface 306 and the exterior wall 310. The protruding wall 314 extends axially from the end wall 312 and circumferentially about the central opening 308. As shown in FIG. 7, the protruding wall 314 is shaped to form a raised inner rim on the end wall 312 of the wheelbase 302. In the example, the protruding wall 314 forms a portion of the inner surface 306 and the inner surface 306 extends continuously axially from a rear wall 316 (shown in FIG. 8) of the wheelbase 302 to the protruding wall 314.

Referring to FIG. 7, the end wall 312 and the exterior wall 310 collectively defines a recess 328 extending circumferentially about the wheelbase 302 at the outer periphery of the wheelbase 302. The recess 328 is sized and positioned to receive the abrasive members 304 (shown in FIG. 8) therein.

In the example embodiment, the inner surface 306 defines a pair of grooves 324, 326. The grooves 324, 326 include a first groove 324 and a second groove 326 axially spaced from the first groove 324. The grooves 324, 326 are semicircular shaped indents that are recessed on the inner surface and are each positioned adjacent a distal end of the protruding wall 314. The grooves 324, 326 each form a ring extending fully circumferentially around the central opening 308 and each within a respective plane transverse to the rotational axis R₂ (shown in FIG. 8). The end wall 312 further includes an outer groove 330 defined radially between the protruding wall 314 and the recess 328. The outer groove 330 extends fully circumferentially about the central opening 308. In other embodiments, the inner surface 306 may include any suitable number of grooves 324, 326. For example, and without limitation, in some embodiments the inner surface 306 includes only a single groove 324.

Referring to FIG. 8, the end wall 312 includes a first surface 332 extending radially from the protruding wall 314 and a second surface 334 extending at least in part axially and at least in part radially from the first surface 332. The second surface 334 extends to the recess 328. In the example embodiment, the outer groove 330 is defined in the second surface 334.

As shown in FIG. 8, the grinding wheel 300 includes abrasive members 304 attached to the wheelbase 302. The abrasive members 304 are substantially the same as the abrasive members 204, shown in FIG. 2. The protruding wall 314 is sized to prevent the grinding water from spraying, in the form of water drops, to the wafer W and the abrasive members 304. The inner grooves 324, 326 on the inner surface 306 of the protruding wall 314 are sized and shaped to restrain a portion of grinding water GW, indicated at “(3”), from instantly escaping from the protruding wall 314 during grinding.

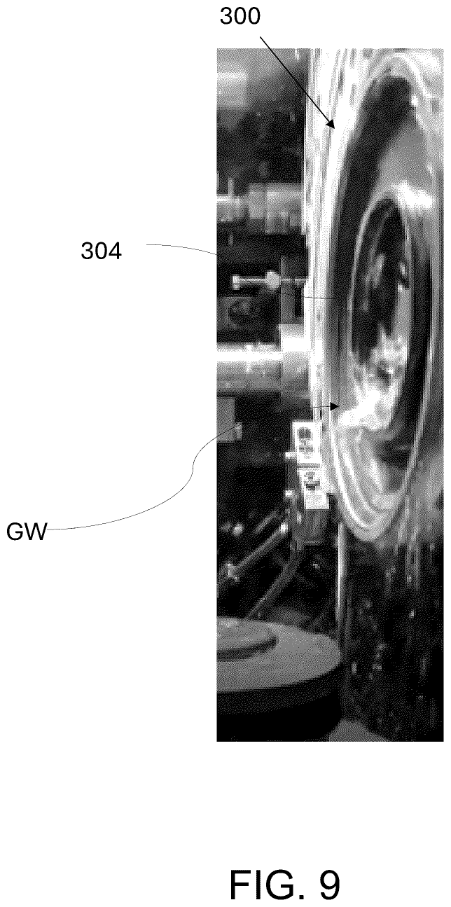

FIG. 9 shows the flow of grinding water GW in the grinding wheel 300 during grinding. The rotating speed of the grinding wheel 300 shown in FIG. 9 is approximately 5,000 rpm. In contrast with the grinding wheel 200 including a conventional wheelbase 202, as shown in FIG. 3, the grinding water GW used with the grinding wheel 300 does not spray out radially towards the wafer W and abrasive stones 304 according to increasing the rotating speed of grinding wheel.

Referring back to FIG. 8, during use, at least a portion of the grinding water supplied through the central opening 308 is captured and rotates within the inner grooves 324, 326 under the centrifugal force by the rotation of the grinding wheel 300. The portion of the grinding water GW within the inner grooves 324, 326, represented in FIG. 8 by the identifier “(3)”, rotates along the inner surface 306 of the protruding wall 314. When the grinding water GW cross the protruding wall 314, because the grinding water GW has been rotated with the wheelbase 302, the grinding water GW is not sprayed along the radiated patterns (1) and (2), shown in FIG. 2, but instead follows the flow path, indicated by the flow arrows 301. In particular, the grinding water GW falls to the first surface 332 and is directed radially outward along the first surface 332 to the second surface 334.

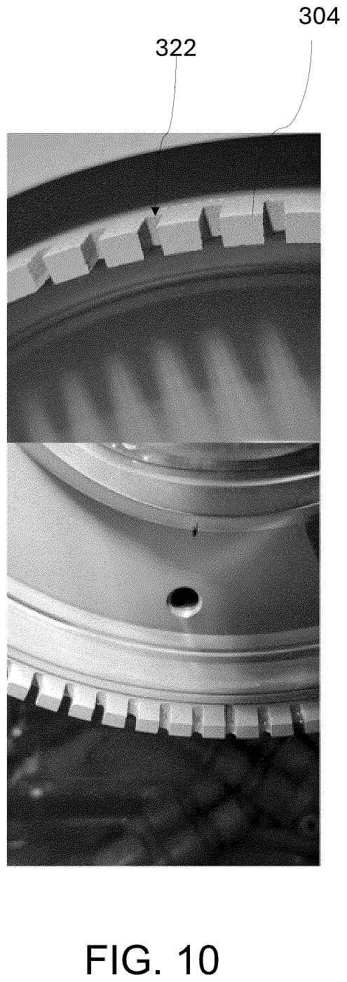

As the grinding water GW reaches the outer groove 330, at least a portion of the grinding water GW is temporarily captured within the outer groove 330 and a flow direction of the grinding water GW changes to, at least in part, an axial direction, indicated by the flow path, indicated at “(2)”. The grinding water GW along the flow path (2) reaches the grinding area between distal ends 320 of the abrasive members 304 and the wafer W (shown in FIG. 1) and is directed back in a partly radial direction. Additionally, at least a portion of the grinding water GW, will flow through the slits 322 (shown in FIG. 10) between the abrasive members 304 along the flow path, indicated at “(1)”. In the example embodiment, an amount of grinding water GW that flows along flow path (1) is less than the amount of grinding water that flows along flow path (2).

In the example embodiment, the flow path of the grinding water GW restrict collision between the grinding water GW, in the form of water droplets, and the surface of abrasive members 304. As a result, the erosion on the surface of high porosity superabrasive stones is reduced with respect to the grinding wheel 200 of FIGS. 2-4.

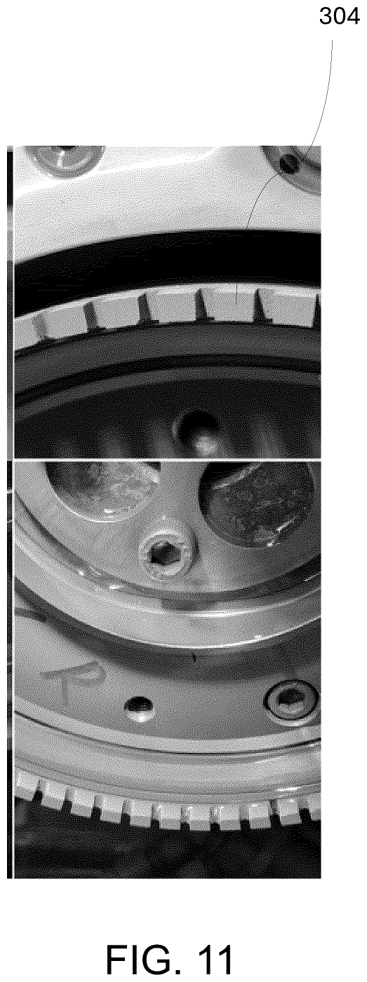

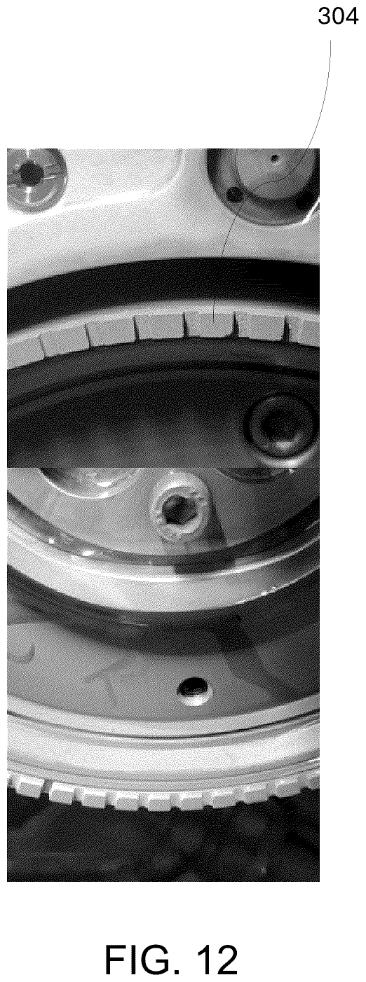

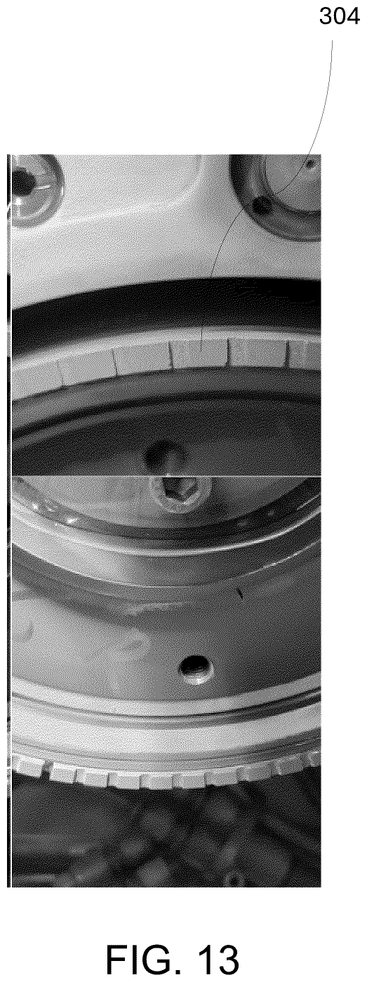

FIGS. 10-13 show images of the abrasive members 304 used with the grinding wheel 300 over a lifespan of the wheel 300. FIG. 10 shows an image of the wheel 300 after grinding 517 wafers, in which the height of the abrasive members 304 was 5.3 millimeters (“mm”). FIG. 11 shows an image of the wheel 300 after grinding 3,195 wafers, in which the height of the abrasive members 304 was 4.2 millimeters (“mm”). FIG. 12 shows an image of the wheel 300 after grinding 8,637 wafers, in which the height of the abrasive members 304 was 1.9 millimeters (“mm”). FIG. 13 shows an image of the wheel 300 after grinding 9,961 wafers, in which the height of the abrasive members 304 was 1.3 millimeters (“mm”). As shown in FIGS. 10-13, erosion on the surface of high porosity superabrasive members 304 was not generated by the collision between the grinding water GW, in the form of water droplet, and the surface of high porosity abrasive members 304 from the beginning of wheel lifespan to the end of wheel lifespan did not form defects in the sides of the members, as shown with respect to FIG. 4.

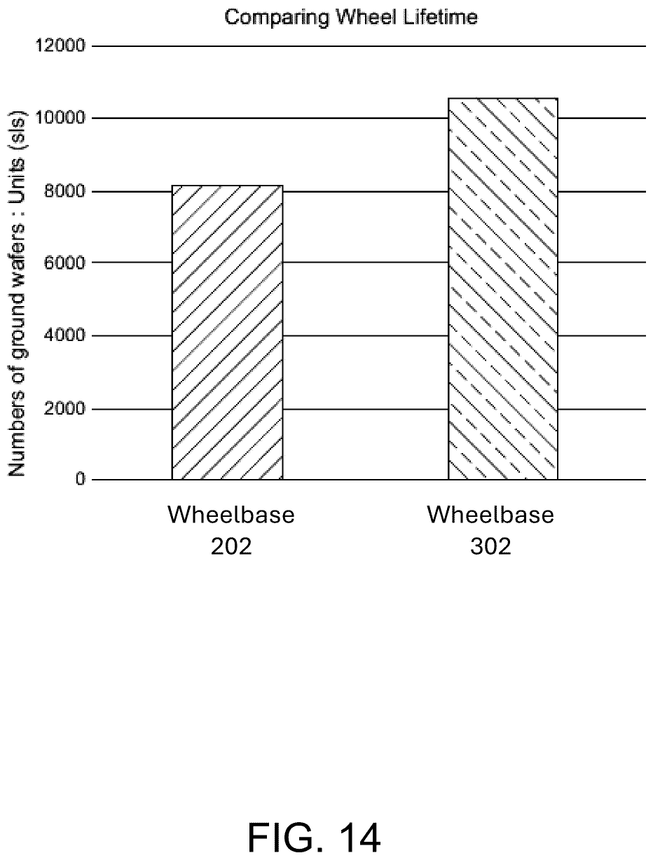

The wheelbase 302 further has a lengthened lifespan, as compared to the wheelbase 302 shown in FIGS. 2-4. As shown in FIGS. 2 and 3, a large amount of grinding water is sprayed, in the form of water droplets, to the wafer and the high porosity super abrasive stones. As a result, the grinding water is not efficiently supplied to the area between the wafer and the distal surfaces of high porosity superabrasive stones. In contrast, as shown in FIG. 8, the wheelbase 302 is shaped to restrict the grinding water from spraying to the surface of the wafer and the high porosity superabrasive stones when ejected from the central opening 308. Additionally, the outer groove 330 facilitates changing the direction of grinding water to flow, at least in part, in the axial direction and along the flow path (2), to reach the grinding area between the wafer and the distal surface of high porosity superabrasive stones. As a result, the efficiency of removal of chips, sludge from the surface of high porosity superabrasive stones is improved which leads to reducing the wear rate of superabrasive stones during grinding cycle and lengthening of the lifespan of the grinding wheel 300. As shown in FIG. 14, the wheelbase 302 has a lifespan of 23% higher than the wheelbase 202.

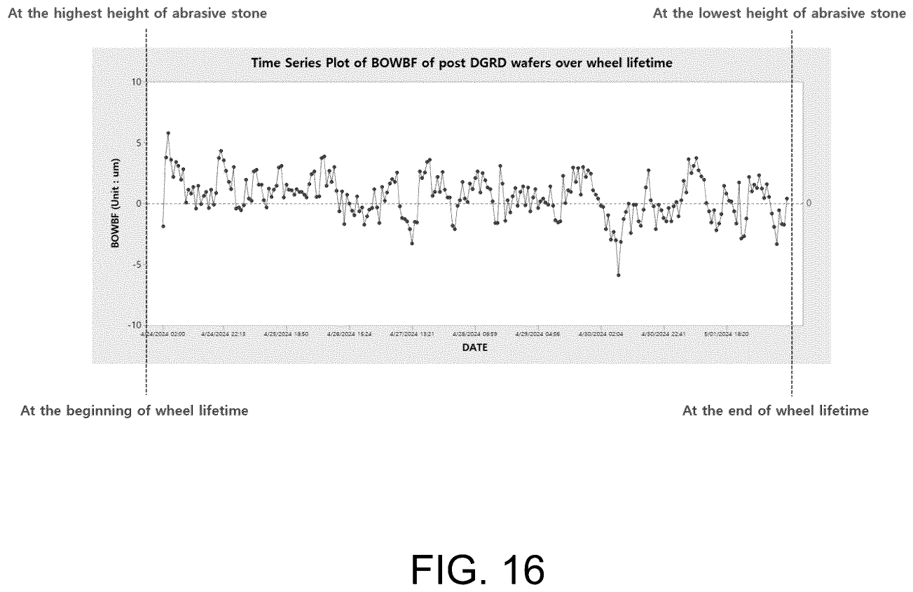

Referring to FIG. 16, in contrast with the conventional wheelbase 202, the wheelbase 302 prevents the formation of negative BOW profile at the beginning of wheel lifespan by increasing the amount of grinding water which is flowing to the distal ends 320 of the abrasive members 304. In particular, the direction of grinding water flow changes to, at least in part, an axial direction, after passing the outer groove 330. As a result, the amount of grinding water can be supplied, efficiently, to the distal ends 320 of the abrasive members 304 at the beginning of wheel lifespan, which leads to increase the efficiency of removal of sludge from the distal ends 320 of abrasive members 304.

As used herein, the terms “about,” “substantially,” “essentially” and “approximately” when used in conjunction with ranges of dimensions, concentrations, temperatures or other physical or chemical properties or characteristics is meant to cover variations that may exist in the upper and/or lower limits of the ranges of the properties or characteristics, including, for example, variations resulting from rounding, measurement methodology or other statistical variation.

When introducing elements of the present disclosure or the embodiment(s) thereof, the articles “a,” “an,” “the,” and “said” are intended to mean that there are one or more of the elements. The terms “comprising,” “including,” “containing,” and “having” are intended to be inclusive and mean that there may be additional elements other than the listed elements. The use of terms indicating a particular orientation (e.g., “top,” “bottom,” “side,” etc.) is for convenience of description and does not require any particular orientation of the item described.

As various changes could be made in the above constructions and methods without departing from the scope of the disclosure, it is intended that all matter contained in the above description and shown in the accompanying drawing[s] shall be interpreted as illustrative and not in a limiting sense.

What is claimed is:

1. A grinding wheel for use with a double-side wafer grinding apparatus, the grinding wheel comprising:
a wheelbase comprising:
an exterior wall;
an inner surface positioned radially within the exterior wall, the inner surface defining a central opening extending axially through the wheelbase;
an end wall extending between the inner surface and the exterior wall; and
a protruding wall extending axially from the end wall and circumferentially about the central opening, wherein the inner surface defines an inner groove extending around the central opening; and
abrasive members attached to the wheelbase and extending axially outward from the end wall.

2. The grinding wheel of claim 1, wherein the grinding wheel is configured to receive a supply of grinding fluid through the central opening during a grinding process in which the grinding wheel is rotated, and wherein the inner groove is shaped such that at least a portion of the grinding fluid supplied through the central opening is captured within the inner groove under centrifugal force by the rotation of the grinding wheel and is rotated with the grinding wheel.

3. The grinding wheel of claim 1, wherein the groove is configured as an indent recessed on the inner surface and is positioned adjacent a distal end of the protruding wall.

4. The grinding wheel of claim 1, wherein the groove is an annular groove extending fully circumferentially around the central opening and within a plane that is transverse to a rotational axis of the grinding wheel.

5. The grinding wheel of claim 1, wherein the end wall defines an outer groove extending circumferentially around the central opening, the outer groove being positioned radially between the abrasive members and the protruding wall.

6. The grinding wheel of claim 5, wherein the grinding wheel is configured to receive a supply of grinding fluid through the central opening during a grinding process in which the grinding wheel is rotated, and wherein the outer groove is shaped such that at least a portion of the grinding fluid flowing along the end wall is captured and redirected to flow, at least in part, in an axial direction by the outer groove.

7. The grinding wheel of claim 5, wherein the end wall includes a first surface extending radially from the protruding wall and a second surface extending obliquely from the first surface, wherein the outer groove is defined in the second surface.

8. The grinding wheel of claim 1, wherein the inner surface of the wheelbase defines an inner surface of the protruding wall, wherein the inner surface of the wheelbase extends axially from the protruding wall to a rear wall of the wheelbase.

9. The grinding wheel of claim 1, wherein the abrasive members are each positioned to be spaced from adjacent abrasive members and define slits therebetween.

10. The grinding wheel of claim 1, wherein the abrasive members include high porosity superabrasive stones, each stone defining pores occupying greater than 50 percent of a total volume of the abrasive members.

11. The grinding wheel of claim 10, wherein each stone defines pores occupying greater than 60 percent of a total volume of the abrasive members.

12. A method for double-sided grinding of a semiconductor structure, the method comprising:
positioning the semiconductor structure between first and second grinding wheels, each grinding wheel comprising:
a wheelbase including an exterior wall, an inner surface positioned radially within the exterior wall and defining a central opening extending axially through the wheelbase, an end wall extending between the inner surface and the exterior wall, and a protruding wall extending axially from the end wall and circumferentially about the central opening, wherein the inner surface defines an inner groove extending around the central opening; and
abrasive members attached to the wheelbase and extending axially outward from the end wall; and
grinding the semiconductor structure by contacting the first and second grinding wheels with the semiconductor structure and rotating the first and second grinding wheels relative to each other.

13. The method of claim 12, wherein grinding the semiconductor structure further comprises:
directing a grinding fluid through the central opening, wherein the inner groove is shaped such that at least a portion of the grinding fluid supplied through the central opening is captured within the inner groove under centrifugal force by the rotation of the grinding wheel and is rotated with the grinding wheel.

14. The method of claim 13, wherein the end wall defines an outer groove extending circumferentially around the central opening, the outer groove being positioned radially between the abrasive members and the protruding wall, and wherein the outer groove is shaped such that at least a portion of the grinding fluid flowing along the end wall is captured by the outer groove and redirected to flow, at least in part, in an axial direction.

15. The method of claim 14, wherein the end wall includes a first surface extending radially from the protruding wall and a second surface extending obliquely from the first surface, wherein the outer groove is defined in the second surface.

16. A double-side grinding apparatus comprising:
first and second grinding wheels, each grinding wheel having a rotational axis and comprising:
a wheelbase comprising:
an exterior wall;
an inner surface positioned radially within the exterior wall, the inner surface defining a central opening extending axially through the wheelbase;
an end wall extending between the inner surface and the exterior wall; and
a protruding wall extending axially from the end wall and circumferentially about the central opening, wherein the inner surface defines an inner groove extending around the central opening; and
abrasive members attached to the wheelbase and extending axially outward from the end wall.

17. The double-side grinding apparatus of claim 16, wherein the grinding wheels are each configured to receive a supply of grinding fluid through the central opening during a grinding process in which the grinding wheels are rotated, and wherein, for each grinding wheel, the inner groove is shaped such that at least a portion of the grinding fluid supplied through the central opening is captured within the inner groove under centrifugal force by the rotation of the grinding wheel and is rotated with the grinding wheel.

18. The double-side grinding apparatus of claim 16, wherein the groove is configured as an indent recessed on the inner surface and is positioned adjacent a distal end of the protruding wall.

19. The double-side grinding apparatus of claim 16, wherein the groove is an annular groove extending fully circumferentially around the central opening and within a plane that is transverse to the rotational axis of the grinding wheel.

20. The double-side grinding apparatus of claim 16, wherein the end wall defines an outer groove extending circumferentially around the central opening, the outer groove being positioned radially between the abrasive members and the protruding wall.
